(19) United States
(12) Patent Application Publication
(10) Pub. No.: US 2011/0062416 A1
(43) Pub. Date: Mar. 17, 2011

(54) NANOWIRE-BASED PHOTODIODE

(76) Inventors: Shih-Yuan Wang, Palo Alto, CA (US); Michael R. Tan, Menlo Park, CA (US)

(21) Appl. No.: 12/990,939

(22) PCT Filed: May 5, 2008
(86) PCT No.: PCT/US08/62683

§ 371 Date: Nov. 3, 2010

(51) Int. Cl. H01L 31/0352; H01L 31/18

(52) U.S. Cl. 257/14; 438/57; 257/E31.032; 977/954

(57) ABSTRACT

A nanowire-based photodiode and an interdigital p-i-n photodiode use an i-type semiconductor nanowire in an i-region of the photodiode. The nanowire-based photodiode includes a first sidewall of a first semiconductor doped with a p-type dopant, a second sidewall of the first semiconductor doped with an n-type dopant, and an intrinsic semiconductor nanowire that spans a trench between the first and second sidewalls. The trench is wider at a top than at a bottom adjacent to a substrate. The first semiconductor of one or both of the first sidewall and the second sidewall is single crystalline and together the first sidewall, the nanowire and the second sidewall form a p-i-n semiconductor junction of the photodiode.

### CROSS-REFERENCE TO RELATED APPLICATIONS

N/A

### STATEMENT REGARDING FEDERALLY SPONSORED RESEARCH OR DEVELOPMENT

N/A

### BACKGROUND

1. Technical Field

The invention relates to photodetectors. In particular, the invention relates to diode photodetectors fabricated using nanostructures.

2. Description of Related Art

Photodiodes are employed in photonic interconnects or communications networks (e.g., fiber optics transmission lines) to receive and process various optical signals. An active region of the photodiode absorbs photons of an optical signal of the photonic communications network. The absorption separates carriers in the photodiode resulting in the photons essentially being converted into an electrical current or signal often called a ‘photocurrent’. The photocurrent then serves as an output of the photodiode. Typically, optics of some form are employed to collect the optical signal from an input source (e.g., a fiber optic cable) and focus the optical signal onto the photodiode. The larger an area of the photodiode (or equivalently the larger surface or receiving area of the active region of a photodiode), the lower are requirements on the optics with respect to focusing. As such, a large area photodiode is desirable in many photonic applications.

Unfortunately, as data rates of the optical signals in photonic interconnects increase, the area of the photodiode employed must generally become smaller leading to higher optics, assembly and testing costs. In particular, characteristics of photodiodes including, but not limited to, junction capacitance and transit time are often related to and tend limit a response time or bandwidth of the photodiode. For example, a conventional photodiode having data rates of greater than 10 Gb/s that is used for photonic interconnects may have a diameter that is limited to about 25-30 microns (μm) by a combination of junction capacitance and transit time. On the other hand, while attractive from an optics standpoint, large area conventional photodiodes having diameters on the order of 100-150 μm or greater cannot provide sufficient bandwidth for the data rates at or exceeding 10 Gb/s. As such, there is considerable interest in providing a means for realizing a relatively large area photodiode (e.g., photodiodes having diameters or side dimensions on the order of 100-150 μm or greater) that exhibits a combination of low junction capacitance and low transit time sufficient to accommodate optical data rates at or exceeding 10 Gb/s. Providing such means would satisfy a long felt need.

### BRIEF SUMMARY

In some embodiments of the present invention, a nanowire-based photodiode is provided. The nanowire-based photodiode comprises a first sidewall. The first sidewall comprises a first semiconductor doped with a p-type dopant. The nanowire-based photodiode further comprises a second sidewall comprising the first semiconductor doped with an n-type dopant. The second sidewall is horizontally spaced apart from the first sidewall on a substrate to form a trench. A top of the trench is wider than a bottom of the trench adjacent to the substrate. The first semiconductor of one or both of the first sidewall and the second sidewall is single crystalline. The nanowire-based photodiode further comprises a nanowire that horizontally spans the trench from the first sidewall to the second sidewall. The nanowire comprises a second semiconductor that is an intrinsic semiconductor. Together, the first sidewall, the nanowire and the second sidewall form a p-i-n photodiode.

In other embodiments of the present invention, an interdigital p-i-n photodiode is provided. The interdigital p-i-n photodiode comprises a plurality of first fingers comprising a p-type semiconductor. The interdigital p-i-n photodiode further comprises a plurality of second fingers comprising an n-type semiconductor. The second fingers are horizontally spaced apart from and interspersed between the first fingers on a substrate to form a plurality of trenches between respective first and second fingers. A top of the trenches is wider than a bottom of the trenches adjacent to the substrate. The interdigital p-i-n photodiode further comprises a plurality of nanowires horizontally spanning the trenches from respective sidewalls of the first fingers to respective sidewalls of the second fingers. The nanowires comprise an i-type semiconductor. Together the first fingers, the nanowires and the second fingers form a plurality of interdigital p-i-n semiconductor junctions.

In other embodiments of the present invention, a method of making a nanowire-based photodiode is provided. The method of making comprises providing a substrate having an insulating substrate. The method of making further comprises forming a first slab comprising a p-type semiconductor and a second slab comprising an n-type semiconductor on the insulating substrate. The second slab is spaced apart from the first slab by a trench that is wider at a top away from the insulating substrate than at a bottom adjacent to the insulating substrate. The method of making further comprises connecting a nanowire across the trench from a sidewall of the first slab to an opposing sidewall of the second slab. The nanowire comprises an i-type semiconductor and the connected nanowire forms a p-i-n semiconductor junction. One or both of the p-type semiconductor and the n-type semiconductor are single crystalline.

Certain embodiments of the present invention have other features that are one or both of in addition to and in lieu of the features described hereinabove. These and other features of the invention are detailed below with reference to the following drawings.

### BRIEF DESCRIPTION OF THE DRAWINGS

The various features of embodiments of the present invention may be more readily understood with reference to the following detailed description taken in conjunction with the accompanying drawings, where like reference numerals designate like structural elements, and in which:

FIG. 1 illustrates a cross sectional view of a nanowire-based photodiode, according to an embodiment of the present invention.

FIG. 2A illustrates a cross sectional view of an interdigital p-i-n photodiode, according to an embodiment of the present invention.

FIG. 2B illustrates a perspective view of the interdigital p-i-n photodiode illustrated in FIG. 2A, according to an embodiment of the present invention.

FIG. 3 illustrates a cross section of an interdigital p-i-n photodiode, according to another embodiment of the present invention.

FIG. 4 illustrates a flow chart of a method of making a nanowire-based photodiode, according to an embodiment of the present invention.

### DETAILED DESCRIPTION

Embodiments of the present invention provide a nanowire-based photodiode that employs an intrinsic ('i-type') or undoped semiconductor nanowire of a p-i-n photodiode. In particular, the i-type semiconductor nanowire bridges between a p-type doped semiconductor and an n-type doped semiconductor to form the p-i-n photodiode, according to the present invention. The bridging nanowire is surrounded by air or another low dielectric constant material. As such, an effective dielectric constant of an intrinsic or i-region of the p-i-n photodiode is lower or considerably lower than that of the i-type semiconductor itself. The lower effective dielectric constant facilitates realizing a p-i-n photodiode of various embodiments having a low capacitance compared to a conventional p-i-n photodiode structure. Moreover, a relatively low transit time of the i-region of the p-i-n photodiode of various embodiments of the present invention may be realized by keeping a length of the nanowire short without significantly increasing the capacitance due to the relatively lower effective dielectric constant. A combination of providing relatively low capacitance and simultaneously facilitating short transit times enables the nanowire-based photodiode of various embodiments of the present invention to provide high bandwidth (e.g., fast or very fast response time). For example, a p-i-n photodiode according to some embodiments of the present invention may be used in a photonic interconnect having greater than a 10 Gb/s bandwidth.

In some embodiments, a large area p-i-n photodiode is provided using the nanowire-based photodiode of the present invention. For example, the large area p-i-n photodiode may have a diameter (e.g., circle) or sides (e.g., of a rectangle) of about 100 to 150 microns (μm). A large area p-i-n photodiode may lessen a requirement on tight focusing of optics used to focus a signal on the p-i-n photodiode, for example. However, as a result of the relatively lower dielectric constant of the nanowire-based photodiode of some embodiments of the present invention, a combination of short transit time and low capacitance may be realized that support high bandwidth operation of such a large area p-i-n photodiode. For example, a 100 to 150 μm diameter or side p-i-n photodiode having a transit time of 10-40 picoseconds (ps) and a capacitance of only a few hundred femtofarads (fF) may be realized according to some embodiments of the present invention.

According to various embodiments, the nanowire-based photodiode of the present invention comprises a p-i-n photodiode structure wherein an i-type region is provided by one or more nanowires that bridge across a trench between a p-type doped semiconductor region and an n-type doped semiconductor region. The p-type semiconductor region and the n-type semiconductor region may be single-crystalline semiconductors formed using conventional deposition methods.

Sidewalls of the trench are sloped or tilted away from a center of the trench in various embodiments. The tilting of the sidewalls facilitates coupling of an incident optical signal into an active region of the p-i-n photodiode where photons are absorbed (e.g., the i-region provided by the nanowire(s)). For example, the tilt of the sidewalls tends to reflect light into the nanowire where the photons may be absorbed. Also, the tilt of the sidewalls may increase an area of the active region relative to non-active regions of the p-i-n photodiode, according to various embodiments of the present invention. For example, in an interdigital p-i-n photodiode, a size of alternating digits or fingers of the p-type and n-type doped semiconductor may be minimized at a receiving surface of the nanowire-based photodiode by tilting the sidewalls of the trench formed by the spaced apart alternating digits. The sloped or tilted sidewalls may also reduce a fringing capacitance leading to a further reduction of the p-i-n photodiode capacitance.

The term ‘nanowire’ as employed herein is defined as an individual quasi-one dimensional, nano-scale, often single crystalline structure typically characterized as having two spatial dimensions or directions that are much less than a third spatial dimension or direction. The presence of the third, greater dimension in nanowires facilitates electron transport along that dimension while conduction is limited in the other two spatial dimensions. Moreover, a nanowire, as defined herein, generally has an axial dimension or length (as a major or third spatial dimension), opposite ends and a solid core. For example, the axial length of a nanowire is typically many times that of a diameter, or equivalently of a width, of the nanowire. A nanowire also may be referred to as a nanowhisker, nanorod or a nanoneedle. A ‘semiconductor nanowire’ is a nanowire comprising a semiconductor. For example, a nanowire may have a diameter that is on the order of about 10 to 100 nm. In addition, the exemplary nanowire may have a diameter that varies (e.g., is variable or non-uniform) along a length of the nanowire. In general, the term ‘nano-scale’ as employed herein refers to dimensions that range from less than about 10 nm to several hundred nanometers.

Nanowires may be formed according to a variety of methodologies. For example, nanowires may be formed by filling a mold comprising nano-scale holes with a material of the nanowires. In particular, a mold or mask having holes is formed on a surface. The holes are then filled with a material that will become the nanowire. In some cases, the mold is removed to leave free-standing nanowires. In other instances, the mold (e.g., SiO₂) may remain. The composition of the material filling the holes may be varied along the length of the nanowire to form a heterostructure and/or a dopant material may be varied along the length to form a semiconductor junction (e.g., a p-i-n junction). In another example, nanowires are grown by self-assembly without a mold.

Nanowires may be grown using a variety of techniques. For example, catalyzed growth includes, but is not limited to, metal-catalyzed growth using one or more of a vapor-liquid-solid (VLS) technique and a vapor-solid (VS) technique, for example. A nanoparticle catalyst is formed on a surface from which the nanowire is to be grown. The growth may be performed in a chemical vapor deposition (CVD) chamber, for example, using a gas mixture comprising precursor nanowire materials and the assistance of the nanoparticle catalyst.

In particular, the nanoparticle catalyst accelerates decomposition of the precursor nanowire material in the gas mixture. Atoms resulting from decomposition of a particular nanowire material-containing gas diffuse through or around the nanoparticle catalyst and precipitate on the underlying substrate. The atoms of the nanowire material precipitate between the nanoparticle catalyst and the surface to initiate nanowire growth. Moreover, catalyzed growth of the nanowire is continued with continued precipitation at the nanoparticle-nanowire interface. Such continued precipitation causes the nanoparticle to remain at the tip of the free end of the growing nanowire. The nanowire growth is continued until a targeted nanowire length is achieved. Other techniques, such as laser ablation for example, also may be used to supply the material forming the growing nanowire. The composition of the material forming the nanowire may be varied along the length of the nanowire to form an axial heterostructure, as mentioned above, or it may be varied in the radial direction to form a radial or “core-shell” heterostructure. Also as mentioned above, the dopant concentration may be varied in magnitude or type to form an electrical junction (e.g., a p-i-n junction).

During catalytic growth, nanowires may grow from the location of the nanoparticle catalyst in a predominately perpendicular direction to a plane of a suitably oriented substrate surface. Under the most common growth conditions, nanowires grow in <111> directions with respect to a crystal lattice and therefore, grow predominately perpendicular to a (111) surface (of a crystal lattice). For (111)-oriented horizontal surfaces, a nanowire will grow predominately vertically relative to the horizontal surface. On (111)-oriented vertical surfaces, a nanowire will grow predominately laterally (i.e., horizontally) relative to the vertical surface.

The use of brackets ‘[ ]’ herein in conjunction with such numbers as ‘111’ and ‘110’ pertains to a direction or orientation of a crystal lattice and is intended to include directions ‘< >’ within its scope, for simplicity herein. The use of parenthesis ‘( )’ herein with respect to such numbers as ‘111’ and ‘110’ pertains to a plane or a planar surface of a crystal lattice and is intended to include planes ‘{ }’ within its scope for simplicity herein. Such uses are intended to follow common crystallographic nomenclature known in the art.

The terms ‘semiconductor’ and ‘semiconductor material’ as used herein independently include, but are not limited to, group IV elemental and compound semiconductors, group III-V compound semiconductors and group II-VI compound semiconductors from the Periodic Table of the Elements, or another semiconductor material that forms any crystal orientation. For example, and not by way of limitation, a semiconductor substrate may be a silicon-on-insulator (SOI) wafer with a (111)-oriented or a (110)-oriented silicon layer (i.e., top layer), or a single, free-standing wafer of (111) silicon, depending on the embodiment. The semiconductor materials, whether part of a substrate or a nanowire, that are rendered electrically conductive, according to some embodiments herein, are doped with a dopant material to impart a targeted amount of electrical conductivity (and possibly other characteristics) depending on the application.

An insulator or an insulator material useful for the various embodiments of the invention is any material that is capable of being made insulating including, but not limited to, a semiconductor material from the groups listed above, another semiconductor material, and an inherently insulating material. Moreover, the insulator material may be an oxide, a carbide, a nitride or an oxynitride of any of the above-referenced semiconductor materials such that insulating properties of the material are facilitated. For example, the insulator may be a silicon oxide (SiOₓ). Alternatively, the insulator may comprise an oxide, a carbide, a nitride or an oxynitride of a metal (e.g., aluminum oxide) or even a combination of multiple, different materials to form a single insulating material or it may be formed from multiple layers of insulating materials.

Semiconductors or semiconductor materials may be essentially undoped or doped. An undoped or unintentionally doped (e.g., lightly doped by stray contaminants) semiconductor is referred to as an ‘intrinsic’ semiconductor, an ‘intrinsically doped’ semiconductor, or an ‘i-type’ semiconductor herein. A doped semiconductor or doped regions within a semiconductor are generally formed adding either an acceptor material (i.e., a p-type dopant) or a donor material (i.e., an n-type dopant) to a semiconductor to produce an extrinsic semiconductor. The process of adding a dopant is known as doping. A semiconductor doped with a p-type dopant is referred to herein as a ‘p-type semiconductor’ and may form or provide a p-region within a semiconductor device or layer. Similarly, a semiconductor doped with an n-type dopant is referred to herein as an ‘n-type semiconductor’ and may form or provide an n-region within a semiconductor device or layer.

A ‘semiconductor junction’ as used herein refers to a junction formed within a semiconductor material between two differently doped regions thereof. A junction between a p-doped region and an n-doped region of the semiconductor material is referred to as a p-n semiconductor junction or simply a p-n junction. The p-n junction includes asymmetrically doped semiconductor junctions such as, but not limited to, p⁺-n junctions where ‘p⁺’ denotes a relatively higher concentration of the p-type dopant or impurity compared to the n-type dopant or impurity. A semiconductor junction in which an intrinsically doped region (i-region) lies between and separates the p-doped region (or ‘p-region’) and the n-doped region (or ‘n-region’) is generally referred to herein as a p-i-n semiconductor junction or simply a p-i-n junction. The term ‘semiconductor junction’ as used herein also refers to complex junctions that may include one or more of layers of different semiconductor materials (e.g., GaAs and GaAlAs), layers of different doping concentrations (e.g., p, p⁺, p⁻, p⁺⁺, n, n⁺, n⁻, n⁺⁺, i, etc.), and doping concentration gradients within and across layers. Further herein, an ‘intrinsically’ doped semiconductor or a related ‘intrinsic’ one of region, layer, and semiconductor is defined as a semiconductor or semiconductor region having a doping concentration that is either essentially undoped (e.g., not intentionally doped) or relatively lightly doped when compared to doping concentrations present in other layers or regions of the semiconductor junction (e.g., p-doped regions or n-doped regions).

As used herein, the ‘active region’ of the semiconductor junction is defined as that portion of the junction that actively participates in the intended operation of the semiconductor junction. For example, the active region of a semiconductor junction in a photodiode is that portion of the junction that absorbs a majority of the photons that produce a photocurrent in the photodiode. In some embodiments, the ‘active region’ is defined as comprising the sum of a depletion region thickness plus a distance equal to a few minority carrier diffusion lengths away from or around the semiconductor junction into the surrounding neutral regions. In a p-i-n photodiode junction, the active region may be essentially confined to an intrinsic region (i.e., the i-region) of the diode junction, for example.

Semiconductor junctions that join different semiconductor materials are defined and referred to herein as either ‘heterostructure junctions’ or simply ‘heterojunctions’. For example, a layer of a first semiconductor material sandwiched between two adjacent layers of a second semiconductor material would be referred to as a heterojunction. Such a heterojunction, wherein the first semiconductor material has a first bandgap and the second semiconductor material has a second band gap, the first bandgap being lower than the second bandgap, is defined herein as a quantum well or a heterojunction quantum well.

Semiconductor junctions between an n-type semiconductor and a p-type semiconductor (of the same or of a different material) are also often referred to as ‘diode junctions’ whether or not an intrinsic layer separates the n-type doped and p-type doped semiconductors. Such diode junctions with an intrinsic nanowire between doped semiconductors are the basis for the various nanowire-based photodiode device embodiments described herein.

In general, a semiconductor used in a semiconductor-based device (e.g., a p-n or p-i-n diode) may be one of single crystalline (i.e., mono-crystalline), polycrystalline, microcrystalline or amorphous (i.e., non-crystalline). Herein, a semiconductor or a semiconductor material that is ‘single crystalline’ has or is characterized by a crystal lattice that is essentially continuous at a micrometer scale. Thus, a single crystalline semiconductor generally exhibits long range (e.g., greater than 100 μm) atomic ordering. A semiconductor wafer that is sliced from a boule that is grown from a seed using the Czochralski process is generally considered single crystalline, for example. Similarly, an epitaxial layer of semiconductor material grown on an insulator layer to form a semiconductor-on-insulator (SOI) substrate may be essentially single crystalline within the epitaxial layer. In contrast, a polycrystalline or microcrystalline semiconductor comprises a number of randomly oriented lattices and lacks long range atomic ordering. Polysilicon used as interconnects and as a top layer on many solar cells is an example of a polycrystalline semiconductor.

For simplicity herein, no distinction is made between a substrate or slab and any layer or structure on the substrate or slab unless such a distinction is necessary for proper understanding. Further, as used herein, the article ‘a’ is intended to have its ordinary meaning in the patent arts, namely ‘one or more’. For example, ‘a layer’ generally means ‘one or more layers’ and as such, ‘the layer’ means ‘the layer(s)’ herein. Also, any reference herein to ‘top’, ‘bottom’, ‘upper’, ‘lower’, ‘up’, ‘down’, ‘left’, ‘right’, ‘vertical’ or ‘horizontal’ is used for discussion purposes and is not intended to be a limitation herein. Moreover, examples herein are intended to be illustrative only and are presented for discussion purposes and not by way of limitation.

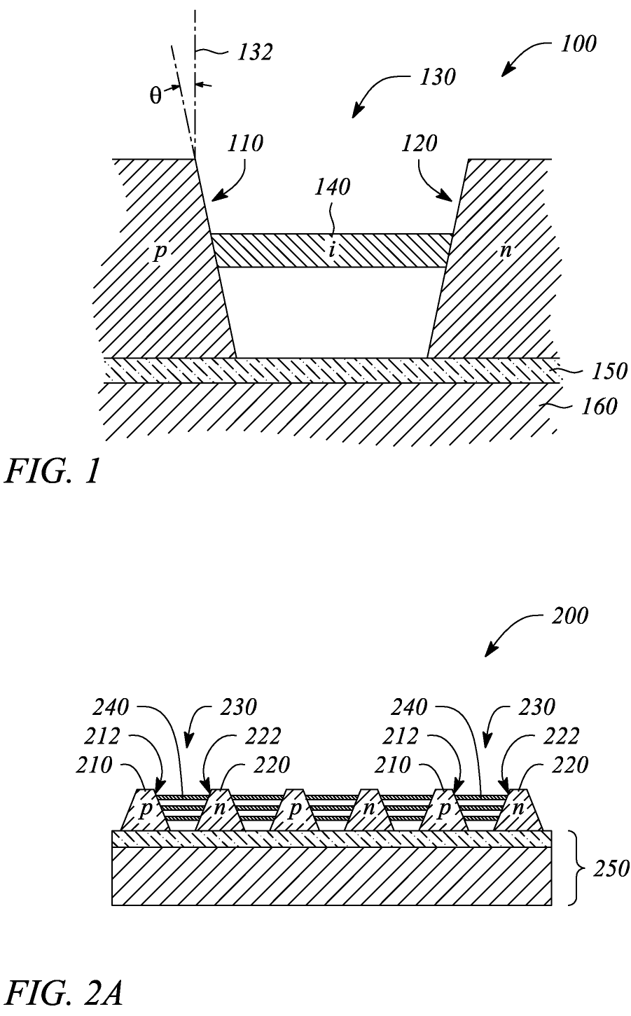

FIG. 1 illustrates a cross sectional view of a nanowire-based photodiode 100, according to an embodiment of the present invention. As illustrated, the nanowire-based photodiode 100 is a p-i-n photodiode. The nanowire-based photodiode 100 absorbs an incident optical signal (e.g., incident photons) in an active region (e.g., an i-region) and generates a photocurrent. The photocurrent is communicated to an external circuit by electrical contacts (not illustrated) connected to a p-region and an n-region of the nanowire-based photodiode 100.

As illustrated, the nanowire-based photodiode 100 comprises a first sidewall 110. The first sidewall 110 comprises a first semiconductor. In some embodiments, the first semiconductor of the first sidewall 110 is essentially single crystalline. In other embodiments, the first semiconductor of the first sidewall 110 is one or more of polycrystalline, microcrystalline and amorphous. The first semiconductor of the first sidewall 110 is doped with a p-type dopant making it a p-type semiconductor. As a p-type semiconductor of the first sidewall 110, the first semiconductor may comprise single crystalline silicon (Si) doped with an acceptor material such as boron (B) or aluminum (Al), for example.

The nanowire-based photodiode 100 further comprises a second sidewall 120. The second sidewall 120 comprises the first semiconductor doped with an n-type dopant making it an n-type semiconductor. In some embodiments, the first semiconductor of the second sidewall 120 is essentially single crystalline. In other embodiments, the first semiconductor of the second sidewall 120 is one or more of polycrystalline, microcrystalline and amorphous. For example, the first semiconductor as an n-type semiconductor of the second sidewall 120 may comprise single crystalline silicon (Si) doped with a donor material, such as one or more of phosphorous (P), arsenic (As) or antimony (Sb).

The second sidewall 120 is horizontally spaced apart from the first sidewall 110. The spacing forms a trench 130 between the first sidewall 110 and the second sidewall 120. The trench 130 generally extends in a vertical direction. In particular, the first and second sidewalls 110, 120 are sidewalls of the trench 130.

The nanowire-based photodiode 100 further comprises a nanowire 140. The nanowire 140 horizontally spans the trench 130 from the first sidewall 110 to the second sidewall 120. FIG. 1 illustrates only one nanowire 140 between the first sidewall 110 and the second sidewall 120 by way of example. In some embodiments, a plurality of nanowires 140 may span the trench 130 from the first sidewall 110 and the second sidewall 120. In particular, the nanowire 140 connects at a first end to the first sidewall 110 and at a second end to the second sidewall 120, according to some embodiments. The respective connections at the first and second ends are intimate connections form a semiconductor junction.

The nanowire 140 comprises a second semiconductor, which may be the same or different from the first semiconductor depending on the embodiment. In some embodiments, the second semiconductor is single crystalline. The second semiconductor comprises an intrinsic or i-type semiconductor, according to some embodiments. In such embodiments, the nanowire 140 comprises the i-type semiconductor. Together the first sidewall 110 (p-type), the nanowire(s) 140 (i-type), and the second sidewall 120 (n-type) form a p-i-n photodiode.

As illustrated in FIG. 1, the nanowire 140 does not fill the trench 130 with the second semiconductor. Instead, there is interstitial space within the trench 130 that is not filled or otherwise occupied by the second semiconductor. In some embodiments, there is considerable interstitial space. For example, the interstitial space may be filled with an ambient atmosphere (e.g., air, a vacuum, etc.) in which the nanowire-based photodiode 100 is immersed. In other embodiments, the interstitial space is filled with another material such as a dielectric material (e.g., an insulating oxide). In some embodiments, the interstitial space filling material has a lower dielectric constant than that of the second semiconductor. In such embodiments, an effective dielectric constant of a region between the first sidewall 110 and the second sidewall 120 is less than a dielectric constant of the second semiconductor.

In some embodiments, the second semiconductor is essentially similar to the first semiconductor. In other embodiments, the first semiconductor and the second semiconductor are different. In some embodiments, the first semiconductor and the second semiconductor have different bandgaps. For example, a bandgap of the second semiconductor may be less than a bandgap of the first semiconductor. In another example, the bandgap of the second semiconductor is greater than a bandgap of the first semiconductor (e.g., quantum well).

In some embodiments, one or both of the first semiconductor and the second semiconductor is a compound semiconductor. In some embodiments, the compound semiconductor may comprise one or both of III-V and II-VI compound semiconductors. For example, the compound semiconductor of the second semiconductor may be a III-V compound semiconductor such as, but not limited to, indium phosphide (InP), gallium arsenide (GaAs), and gallium aluminum arsenide (GaAlAs), while the first semiconductor is a group VI elemental semiconductor such as, but not limited to, silicon (Si) or Germanium (Ge). In another example, the first semiconductor is III-V compound semiconductor, such as GaAs, and the second semiconductor is a different III-V compound semiconductor, such as GaAlAs. In some embodiments, the first semiconductor may comprise a compound semiconductor that is different from and has either a smaller or a larger bandgap than the compound semiconductor of the second semiconductor.

In some embodiments, a top of the trench 130 is wider than a bottom of the trench 130. In particular, one or both of the first sidewall 110 and the second sidewall 120 are tilted away from a center of the trench 130 at a tilt angle θ relative to a vertical axis 132, as illustrated in FIG. 1. In some embodiments, the tilt angle θ is greater than about 5 degrees but less than about 45 degrees. In some embodiments, the tilt angle θ is between about 10 degrees and about 30 degrees. In some embodiments, an average width of the trench 130 is greater than about one minority carrier diffusion length of the second semiconductor. For example, an average width of the trench when the second semiconductor is InP may be in a range of about 1-4 μm.

In some embodiments, when the first semiconductor is essentially single crystalline, the single crystalline first semiconductor comprises a (111) crystal lattice plane that is vertically oriented and coextensive with at least a portion of a length of the trench 130. In such embodiments, a <111> direction of the crystal lattice is essentially directed across the trench. For example, the first semiconductor of the first sidewall 110 may be single crystalline and have the aforementioned vertically oriented and coextensive (111) crystal lattice plane. The exemplary first sidewall 110 forms a trench sidewall and the <111> direction of the crystal lattice points across the trench 130 toward the second sidewall 120. Since nanowires are known to preferentially grow in the <111> direction, the nanowire 140 grown from the first sidewall 110 will preferentially grown toward the second sidewall 120 for this example. Moreover, the nanowire 140 will tend to grow horizontally across the trench 130 even when the first sidewall 110 is tilted away from the center of the trench 130 (e.g., as illustrated in FIG. 1).

In some embodiments, the nanowire-based photodiode 100 further comprises an insulating surface layer 150 of a substrate 160. In some embodiments, the entire substrate 160 may be insulating (e.g., a sapphire substrate, a semi-insulating InP substrate or semi-insulating GaAs substrate) in which case the substrate 160 essentially comprise the insulating surface layer 150. In other embodiments, the insulating surface layer 150 is a layer of an insulating material deposited or otherwise formed on a surface of the substrate 160 (i.e., as illustrated in FIG. 1). For example, the substrate 160 may be a silicon (Si) substrate with a silicon dioxide (SiO₂) insulating surface layer 150. In yet other embodiments, the insulating surface layer 150 is replaced by another layer (not illustrated) that provides electrical isolation between the p-type semiconductor of the first sidewall 110 and the n-type semiconductor of the second sidewall 120. In some embodiments, the insulating layer 150 inhibits nanowires 140 from forming (e.g., growing) on or connecting to the insulating layer 150.

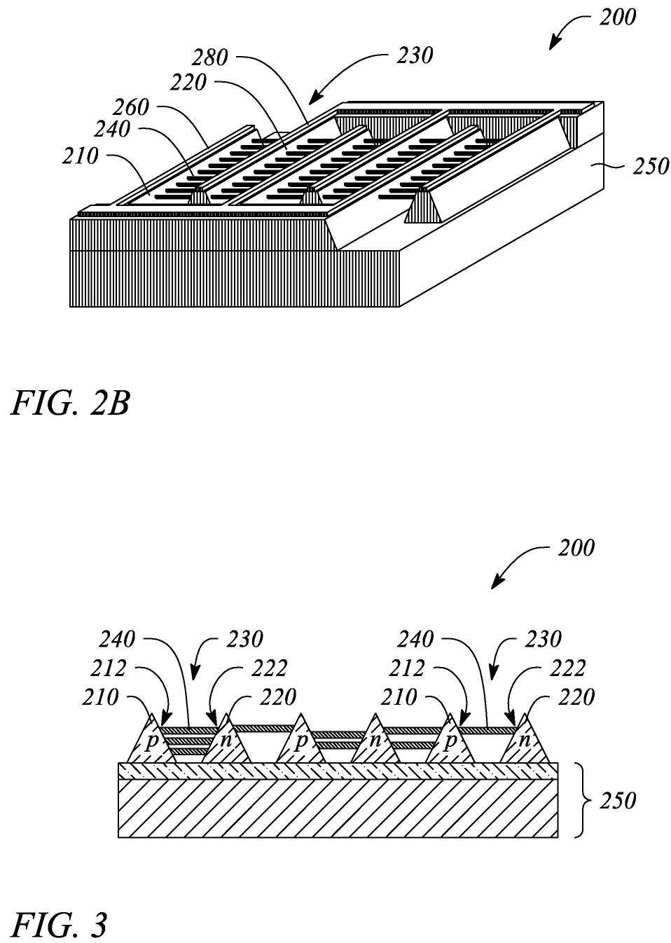

FIG. 2A illustrates a cross sectional view of an interdigital p-i-n photodiode 200, according to an embodiment of the present invention. FIG. 2B illustrates a perspective view of the interdigital p-i-n photodiode 200 illustrated in FIG. 2A, according to an embodiment of the present invention. FIG. 3 illustrates a cross sectional view of an interdigital p-i-n photodiode 200, according to another embodiment of the present invention.

The interdigital p-i-n photodiode 200 comprises a plurality of first digits or ‘fingers’ 210. Each first finger 210 comprises a p-type semiconductor. In some embodiments, the p-type semiconductor is essentially single crystalline. In such embodiments, the first fingers 210 are essentially strips of single crystalline p-type semiconductor. Each first finger 210 has a sidewall 212. In some embodiments, the sidewalls 212 of the plurality of first fingers 210 are essentially similar to the first sidewall 110 described above with respect to the nanowire-based photodiode 100.

The interdigital p-i-n photodiode 200 further comprises a plurality of second digits or ‘fingers’ 220. Each second finger 220 comprises an n-type semiconductor. In some embodiments, the n-type semiconductor is essentially single crystalline. In such embodiments, the second fingers 220 are essentially strips of single crystalline n-type semiconductor. Each second finger 220 has a sidewall 222. In some embodiments, the sidewalls 222 of the plurality of second fingers 220 are essentially similar to the second sidewall 120 described above with respect to the nanowire-based photodiode 100.

The individual ones of the second fingers 220 are horizontally spaced apart from and interspersed between individual ones of the first fingers 210. The spaced, interspersed pluralities of first fingers 210 and second fingers 220 form a plurality of trenches 230 between respective first and second fingers 210, 220 of the respective pluralities. A top of each trench 230 is wider than a bottom of the trench 230. In some embodiments, the trenches 230 are essentially similar to the trench 130 described above with respect to the nanowire-based photodiode 100.

The interdigital p-i-n photodiode 200 further comprises a plurality of nanowires 240 horizontally spanning individual trenches 230 of the plurality of trenches. Specifically, the nanowires 240 span from respective sidewalls 212 of the first fingers 210 to respective sidewalls 222 of the second fingers 220. The nanowires 240 comprise an i-type semiconductor. In some embodiments, the nanowires 240 of the plurality are essentially similar to the nanowire 140 described above with respect to the nanowire-based photodiode 100. In particular, in some embodiments, the i-type semiconductor comprises a compound semiconductor having a bandgap that is smaller than a bandgap of one or both of the p-type semiconductor of the first fingers 210 and the n-type semiconductor of the second fingers 220.

The trenches 230 of the interdigital p-i-n photodiode 200 have a dielectric constant that is dictated by an environment that fills the trenches 230, as described above for trench 130. In some embodiments, an effective dielectric constant of the trenches 230 is less than a dielectric constant of the i-type semiconductor of the plurality of nanowires 240.

In some embodiments, the interdigital p-i-n photodiode 200 further comprises an insulating substrate 250. The insulating substrate 250 supports the plurality of first fingers 210 and the plurality of second fingers 220. For example, the insulating substrate 250 may comprise an insulator-on-semiconductor substrate. In some embodiments, the insulating substrate 250 is essentially similar to the insulating surface 150 and the substrate 160 described above with respect to the nanowire-based photodiode 100.

In some embodiments, the interdigital p-i-n photodiode 200 further comprises a first conductor layer and a second conductor layer in electrical contact with the plurality of first fingers 210 and the plurality of second fingers 220, respectively. FIG. 2B illustrates a first conductor layer 260 on an interconnecting arm of the plurality of first fingers 210 and a second conductor layer 280 on an interconnecting arm of the plurality of second fingers 220, by way of example. In some embodiments, the first conductor layer 260 is provided on a top surface of each of the first fingers 210 of the plurality. The first conductive layer 260 electrically interconnects and reduces a collective series resistance of the plurality of first fingers 210. In some embodiments, the second conductor layer 280 is provided on a top surface of each of the second fingers 220 of the plurality. The second conductive layer 280 electrically interconnects and reduces a collective series resistance of the plurality of second fingers 220. For example, the first conductor layer 260 and second conductor layer 280 may comprise a metal deposited by evaporation or sputtering on to and along the top surface of the respective fingers 210, 220. In another example, the first and second conductor layers 260, 280 comprise a polysilicon interconnect (e.g., heavily doped polysilicon layer).

In some embodiments, an individual finger of one or both of the plurality of first fingers 210 and the plurality of the second fingers 220 has a cross sectional shape that is one of a triangle and a trapezoid. For example, FIG. 2A illustrates first and second fingers 210, 220 of the respective pluralities having a trapezoidal cross sectional shape. FIG. 3 illustrates first and second fingers 210, 220 of the respective pluralities having a triangular cross sectional shape. The triangular and trapezoidal cross sectional shapes of the respective fingers 210, 220 have a respective sidewall 212, 222 angle relative to a vertical axis (not illustrated). Herein, the sidewall angle is measured and defined in a direction away from a center of the trench 230, as was illustrated in FIG. 1 with respect to sidewall angle θ. In some embodiments, the sidewall angle is greater than about 5 degrees. In some embodiments, the sidewall angle is less than or equal to 45 degrees.

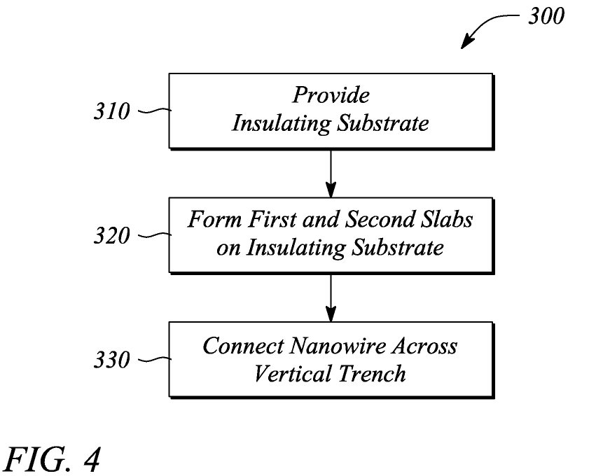

FIG. 4 illustrates a flow chart of a method 300 of making a nanowire-based photodiode, according to an embodiment of the present invention. The method 300 of making a nanowire-based photodiode comprises providing 310 an insulating substrate. For example, the insulating substrate may be a substrate having an insulating layer (e.g., an SOI substrate). The method 300 of making a nanowire-based photodiode further comprises forming 320 a first slab comprising a p-type semiconductor and a second slab comprising an n-type semiconductor on the insulating substrate. When formed 320, the second slab is spaced apart from the first slab by a trench. Further, the trench is wider at a top of the trench, which is away from the insulating substrate, than at a bottom of the trench that is adjacent to the insulating substrate. For example, the first and second slabs that are spaced apart by the trench may be essentially similar to the first fingers 210 and the second fingers 220 that are spaced apart by the trench 230, as illustrated in one or more of FIGS. 2A, 2B and 3, and described above with respect to the interdigital p-i-n photodiode 200.

The method 300 of making a nanowire-based photodiode further comprises connecting 330 a nanowire across the trench. In particular, the nanowire is connected 330 from a sidewall of the first slab to an opposing sidewall of the second slab such that a semiconductor junction is formed. The nanowire comprises an i-type semiconductor. Connecting 330 a nanowire provides a p-i-n photodiode. In some embodiments, one or both of the p-type semiconductor and the n-type semiconductor are single crystalline.

In some embodiments, forming 320 a first slab and a second slab comprises depositing a single crystalline semiconductor on the insulating substrate. Forming 320 a first slab and a second slab further comprises etching the single crystalline semiconductor to define the first slab and the second slab separated by the trench. In some embodiments, etching produces sidewalls of one or both of the first slab and the second slab having a tilt angle θ relative to a vertical axis. The tilt angle θ is generally away from a center of the trench. In some embodiments, the tilt angle θ is greater than about 5 degrees but less than or equal to 45 degrees. In some embodiments, the tilt angle θ is less than about 30 degrees. In some embodiments, the tilt angle θ is greater than about 10 degrees.

For example, a semi-insulating single crystal substrate, such as InP or GaAs, may be masked using a dielectric mask that has openings corresponding to a set of first interdigital fingers (e.g., p-type AlGaAs when starting with a GaAs substrate). The masking may have openings defined by standard photolithographic process, for example. Either dry or wet etching may be employed create the openings. The dielectric mask may be silicon nitride or silicon dioxide, for example. The masked substrate is then place in an organo-metallic vapor phase epitaxial (OMVPE) reactor to grow the p-type AlGaAs fingers selectively in the openings of the mask. Once the first interdigital fingers (i.e., the p-type AlGaAs fingers) are grown on the substrate, the process is repeated at new offset locations to form the n-type AlGaAs interdigital fingers using the OMVPE reactor with n-type AlGaAs growth. The nanowire may be GaAs, InGaAs, InP with smaller bandgap than that of the fingers, for example. The fingers need not be transparent to the incident radiation. In some cases not using transparent fingers may minimize a slow response due to carriers generated in the fingers diffusing into the high field region, the i-type semiconductor of the nanowire.

In some embodiments, connecting 330 a nanowire to the first slab and the second slab across the trench comprises growing the nanowire in situ using any of the methods described above for nanowire growth. In some embodiments, the nanowire is similar to any of the embodiments of the nanowire 140, 240 described above for the photodiode 100, 200.

In some embodiments, the method 300 of making a nanowire-based photodiode further comprises forming an electrical contact to the first slab and an electrical contact to the second slab. The electrical contacts provide a path for a photocurrent produced at the semiconductor junction to exit the nanowire-based photodiode. The electrical contacts may be formed by sputtering or evaporation of metal or depositing a heavily doped polysilicon, for example, on a respective top surface of the first and second slabs. In some embodiments, the electrical contacts are similar to the first and second conductor layers, including first and second conductor layers 260, 280, described above for the interdigital photodiode 200.

Thus, there have been described embodiments of a nanowire-based photodiode, an interdigital p-i-n photodiode, and a method of making a nanowire-based photodiode using an i-type semiconductor nanowire in an i-region of the photodiode. It should be understood that the above-described embodiments are merely illustrative of some of the many specific embodiments that represent the principles of the present invention. Clearly, those skilled in the art can readily devise numerous other arrangements without departing from the scope of the present invention as defined by the following claims.

What is claimed is:

1. A nanowire-based photodiode comprising:
a first sidewall comprising a first semiconductor doped with a p-type dopant;
a second sidewall comprising the first semiconductor doped with an n-type dopant, the second sidewall being horizontally spaced apart from the first sidewall on a substrate to form a trench, wherein a top of the trench is wider than a bottom of the trench adjacent to the substrate, the first semiconductor of one or both of the first sidewall and the second sidewall being single crystalline; and
a nanowire that horizontally spans the trench from the first sidewall to the second sidewall, the nanowire comprising a second semiconductor that is an intrinsic semiconductor,
wherein the first sidewall, the nanowire and the second sidewall together form a p-i-n photodiode.

2. The nanowire-based photodiode of claim 1, wherein an effective dielectric constant of a region in the trench between the first sidewall and the second sidewall is less than a dielectric constant of the second semiconductor.

3. The nanowire-based photodiode of claim 1, wherein a bandgap of the second semiconductor is less than a bandgap of the first semiconductor.

4. The nanowire-based photodiode of claim 1, wherein the second semiconductor comprises a compound semiconductor.

5. The nanowire-based photodiode of claim 4, wherein the compound semiconductor is a III-V compound semiconductor.

6. The nanowire-based photodiode of claim 4, wherein the first semiconductor comprises a compound semiconductor that is different from and has a larger bandgap than the compound semiconductor of the second semiconductor.

7. The nanowire-based photodiode of claim 1, wherein the first semiconductor comprises silicon (Si) and the second semiconductor comprises one or more of indium phosphide (InP), gallium arsenide (GaAs), and gallium aluminum arsenide (GaAlAs).

8. The nanowire-based photodiode of claim 1, wherein one or both of the first sidewall and the second sidewall are tilted away from a center of the trench at a tilt angle relative to a vertical axis, the tilt angle being greater than about 5 degrees but less than about 45 degrees.

9. The nanowire-based photodiode of claim 8, wherein the tilt angle is between about 10 degrees and about 30 degrees.

10. The nanowire-based photodiode of claim 1, wherein one or both of the first sidewall and the second sidewall are tilted away from a center of the trench, an average width of the trench being greater than about one minority carrier diffusion length of the second semiconductor.

11. The nanowire-based photodiode of claim 1, wherein the single crystalline first semiconductor comprises a (111) crystal lattice plane that is both vertically oriented and coextensive with at least a portion of a length of the trench such that a <111> direction of the crystal lattice is essentially directed across the trench.

12. The nanowire-based photodiode of claim 1, wherein the substrate comprises an insulating surface layer, the insulating surface layer electrically isolating the first sidewall from the second sidewall.

13. The nanowire-based photodiode of claim 1 used in an interdigital p-i-n photodiode, the interdigital p-i-n photodiode comprising:
a plurality of first fingers, the first fingers comprising the first semiconductor doped with the p-type dopant, a sidewall of one or more of the first fingers being the first sidewall, the first fingers being interconnected with one another;
a plurality of second fingers, the second fingers comprising the first semiconductor doped with the n-type dopant, a sidewall of one or more of the second fingers being the second sidewall, the second fingers being interconnected with one another, the second fingers further being interspersed with the first fingers such that a plurality of the trenches spaces apart adjacent ones of the first fingers and the second fingers; and
a plurality of the nanowires horizontally spanning the trenches to form a corresponding plurality of p-i-n junctions,
wherein the interdigital p-i-n photodiode facilitates reception of high modulation rate optical signals.

14. An interdigital p-i-n photodiode comprising:
a plurality of first fingers comprising a p-type semiconductor;
a plurality of second fingers comprising an n-type semiconductor, the second fingers being horizontally spaced apart from and interspersed between the first fingers on a substrate to form a plurality of trenches between respective first and second fingers, wherein a top of the trenches is wider than a bottom of the trenches adjacent to the substrate; and
a plurality of nanowires horizontally spanning the trenches from respective sidewalls of the first fingers to respective sidewalls of the second fingers, the nanowires comprising an i-type semiconductor,
wherein together the first fingers, the nanowires and the second fingers together form a plurality of interdigital p-i-n semiconductor junctions.

15. The interdigital p-i-n photodiode of claim 14, further comprising:
a first conductor layer electrically connecting to the plurality of first fingers, the first conductive layer reducing a collective series resistance of the plurality of first fingers; and
a second conductive layer electrically connecting to the plurality of second fingers, second conductive layer reducing a collective series resistance of the plurality of second fingers,
wherein the substrate comprises an insulating layer, the plurality of first fingers and the plurality of second fingers being supported on the insulating layer.

16. The interdigital p-i-n photodiode of claim 14, wherein the i-type semiconductor comprises a compound semiconductor having a bandgap that is less than a bandgap of either the p-type semiconductor of the first fingers or the n-type semiconductor of the second fingers.

17. The interdigital p-i-n photodiode of claim 14, wherein a cross sectional shape a finger of one or both of the plurality of first fingers and the plurality of second fingers is one of a triangle and a trapezoid having a sidewall angle relative to a vertical axis of greater than about 5 degrees and less than or equal to 45 degrees.

18. The interdigital p-i-n photodiode of claim 14, wherein one or both of the p-type semiconductor and the n-type semiconductor are single crystalline and wherein an effective dielectric constant within the trenches is less than a dielectric constant of the i-type semiconductor.

19. A method of making a nanowire-based photodiode, the method comprising:
providing an insulating substrate;
forming a first slab comprising a p-type semiconductor and a second slab comprising an n-type semiconductor on the insulating substrate, the second slab being spaced apart from the first slab by a trench that is wider at a top away from the insulating substrate than at a bottom adjacent to the insulating substrate; and
connecting a nanowire across the trench from a sidewall of the first slab to an opposing sidewall of the second slab, the nanowire comprising an i-type semiconductor such that a p-i-n semiconductor junction is formed,
wherein one or both of the p-type semiconductor and the n-type semiconductor are single crystalline.

20. The method of making a nanowire-based photodiode of claim 19, wherein forming a first slab and a second slab on the insulating substrate comprises:
depositing a single crystalline semiconductor on the insulating substrate;
etching the single crystalline semiconductor to define the first slab and the second slab separated by the trench, the trench having a respective slab sidewall with a tilt angle relative to a vertical axis that is greater than about 5 degrees but less than or equal to 45 degrees; and
doping the first slab to produce the p-type semiconductor and doping the second slab to produce the n-type semiconductor, and
wherein connecting a nanowire comprises growing one or more nanowires from the sidewall of one or both of the first slab and the second slab until the nanowires connect to the respective opposing sidewall.
